(19) United States
(12) Patent Application Publication
(10) Pub. No.: US 2002/0142095 A1
(43) Pub. Date: Oct. 3, 2002

(54) Method of forming a film by vacuum ultraviolet irradiation

(76) Inventors: Yoshikazu Motoyama, Miyazaki (JP); Kiyohiko Toshikawa, Miyazaki (JP); Yosuke Motokawa, Miyazaki (JP); Junichi Miyano, Miyazaki (JP); Hiroyuki Mutoh, Miyazaki (JP); Ko Kurosawa, Miyazaki (JP); Atsushi Yokotani, Miyazaki (JP)

Correspondence Address: VOLENTINE FRANCOS, PLLC, Suite 150, 12200 Sunrise Vally Drive, Reston, VA, 20191, US

(21) Appl. No.: 10/105,382

(22) Filed: Mar. 26, 2002

(30) Foreign Application Priority Data
Mar. 30, 2001 (JP) 098720/2001

(51) Int. Cl. C23C 16/00; B05D 3/06

(52) U.S. Cl. 427/255.6; 427/558; 427/294

(57) ABSTRACT

A method of forming a film on a base member disposed in a reactor comprises introducing an organic gas into the reactor for use as a starting material for the film, and a dilute gas including an inert gas, irradiating a surface of the base member with vacuum ultraviolet rays; and forming the film on the base member under a normal pressure atmosphere.

### BACKGROUND OF THE INVENTION

The present invention relates to a method of forming a film on a base member such as a silicon semiconductor substrate by vacuum ultraviolet irradiation, and a CVD (Chemical Vapor Deposition) system used in executing the same, and in particular, to a method capable of forming the film under a normal pressure environment, and a CVD system for executing the same.

There has been available a photo CVD method as one of conventional methods of forming a film on a base member such as a silicon semiconductor substrate, glass fiber, and so forth. With a CVD system for executing the photo CVD method, the base member is disposed in a reactor thereof, and the reactor is placed in a vacuum environment.

An organic gas such as tetraethoxy orthosilicate gas [Si(OC₂H₅)₄] for use as a starting material for the film is fed into the reactor as necessary. Within the CVD system, the surface of the base member is irradiated through the organic gas with vacuum ultraviolet rays from, for example, an eximer lamp light source in the vacuum environment in order to form a film on the base member.

With the conventional CVD system described above, since a film is formed on the base member inside the reactor placed in the vacuum environment, it is desirable to install suitable vacuum equipment. However, because it generally requires a high cost to introduce and maintain such a vacuum equipment, it has been desired that the photo CVD can be executed in an economical and easy way.

### SUMMARY OF THE INVENTION

The present invention may provide a method of forming a film on a base member, enabling the photo CVD to be executed economically and easily under a normal pressure environment without requiring the vacuum environment.

The invention is based on the basic concept that vacuum ultraviolet rays can be effectively irradiated onto the base member on which the film is to be formed under the normal pressure environment by keeping the inside of a reactor of the CVD system in a nitrogen atmosphere or an inert gas atmosphere.

A method of forming a film on a base member disposed in a reactor of the present invention comprises introducing an organic gas into the reactor for use as a starting material for the film, and a dilute gas including an inert gas, irradiating a surface of the base member with vacuum ultraviolet rays; and forming the film on the base member under a normal pressure atmosphere.

### BRIEF DESCRIPTION OF THE DRAWINGS

FIG. 1 is a schematic illustration showing the constitution of an embodiment 1 of a CVD system 101 according to the invention;

FIG. 2 is a graph showing results of a spectrochemical analysis of a silicon oxide film obtained according to the invention, conducted by FT-IR;

FIG. 3 is a sectional view of an embodiment 2 of a CVD system according to the invention;

FIG. 4 is a schematic illustration showing a top view of the embodiment 2 of the CVD system according to the invention;

FIG. 5 is a schematic illustration showing the constitution of an embodiment 3 of a CVD system according to the invention;

FIG. 6 is a schematic illustration showing the constitution of an embodiment 4 of a CVD system according to the invention;

FIG. 7 is a schematic illustration showing the constitution of an embodiment 5 of a CVD system according to the invention;

FIG. 8 is a side elevation of an embodiment 6 of a CVD system according to the invention; and

FIG. 9 is a cross-sectional view of the CVD system shown in FIG. 8.

### DETAILED DESCRIPTION OF THE PREFERRED EMBODIMENTS

Embodiments of the invention are described in detail hereinafter with reference to the accompanying drawings.

Embodiment 1

An embodiment 1 of a CVD system 101 according to the invention is used for forming an insulation film such as a silicon oxide film in the process of fabricating a semiconductor device such as a MOS transistor.

With the CVD system 101, use is made of a tetraethoxy orthosilicate gas (TEOS gas), well known as a stock gas used as a starting material of the insulation film. Further, use is made of vacuum ultraviolet rays to excite the tetraethoxy orthosilicate gas so as to form the insulation film, and for the vacuum ultraviolet rays, use is made of xenon (Xe₂) light rays at a wavelength of 172 nm.

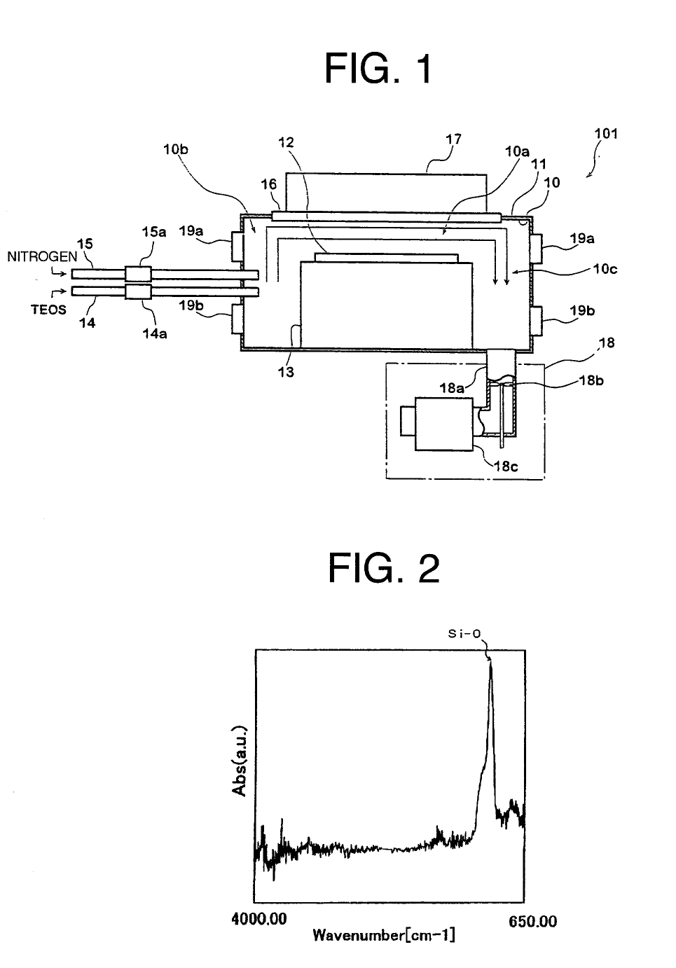

As shown in FIG. 1, the CVD system 101 comprises a housing 11 in the shape of a rectangular cylinder as a whole, defining a reactor 10 extending substantially in the horizontal direction, a susceptor 13 for retaining a silicon semiconductor substrate 12 disposed inside the reactor 10, as a base member on which the film is to be formed, having a temperature control function for enabling temperature control of the silicon semiconductor substrate 12, a stock gas feed tube 14 for guiding the tetraethoxy orthosilicate gas as the starting material of the insulation film from one longitudinal end of the housing 11 into the reactor 10, a dilute gas feed tube 15 for guiding a dilute gas for the tetraethoxy orthosilicate gas from the one end as described of the housing 11 into the reactor 10, an eximer lamp 17 which is a light source of the xenon light rays for causing excitation of the tetraethoxy orthosilicate gas, used for irradiation of the silicon semiconductor substrate 12 disposed on the susceptor 13 with the xenon light rays through a transmissive window 16 provided in the housing 11, and an exhaust mechanism 18 disposed on the other end of the housing 11, more specifically, in close proximity to the other end of the reactor, for causing the tetraethoxy orthosilicate gas and the dilute gas to form horizontal and orderly flows moving from the one end to the other end of the housing 11 therein. On the sidewalls of the housing 11, defining the opposite ends thereof, in a longitudinal direction, there are installed an upper heater 19a and a lower heater 19b for raising temperature inside the reactor 10 as necessary, respectively.

With the CVD system 101 according to the embodiment 1, nitrogen gas is used as the dilute gas for the tetraethoxy orthosilicate gas. However, in place of the nitrogen gas, an inert gas such as helium, neon, argon, and so forth may be also used.

The housing 11 can be made up of a stainless steel material. The transmissive window 16 can be formed of, for example, a synthetic quartz, and is provided with a temperature control function.

At both longitudinal ends of the reactor 10 of the housing 11, an inlet part 10b through which the tetraethoxy orthosilicate gas and the dilute gas are fed into the reactor 10, and an outlet part 10c through which both the gases fed through the inlet part 10b are discharged are defined, respectively.

The susceptor 13 is disposed inside the reactor 10 so as to face the transmissive window 16, and is protruded towards the transmissive window 16. As a result, there is defined a necked-down part 10a smaller in diameter than the inlet part 10b and the outlet part 10c, respectively, between the inlet part 10b and the outlet part 10c, that is, in a flow path of the respective gases flowing from the one end of the reactor 10 to the other end thereof.

The stock gas feed tube 14 and the dilute gas feed tube 15 are provided with a heater 14a and a heater 15a, respectively, for maintaining the temperature of the respective gases at predetermined temperatures.

The exhaust mechanism 18 comprises an exhaust tube 18a disposed under the lower part of the housing 11, in close proximity to the other end thereof, and connected thereto, an exhaust fan 18b installed inside the exhaust tube 18a for prompting discharge of the gases to be charged from the reactor 10, and a dust collector 18c provided with capturing means such as an activated carbon filter, a cold trap, and so forth, for removal of deleterious constituents of an exhaust gas.

In the CVD system 101, nitrogen gas is fed into the reactor 10 in a non-vacuum condition via the dilute gas feed tube 15, whereupon the exhaust mechanism 18 starts an exhaust operation in order to keep the inside of the reactor 10 in a nitrogen atmosphere. When the reactor 10 is kept in the nitrogen atmosphere, a predetermined amount of the tetraethoxy orthosilicate gas is fed into the reactor 10 via the stock gas feed tube 14. The exhaust mechanism 18 continues operation to keep the reactor 10 at normal pressure.

Prior to feeding of nitrogen gas as described above, the inside of the reactor 10 may be placed in a vacuum condition in order to remove beforehand constituents of the air present within the reactor 10, and subsequently, nitrogen gas can be fed.

When tetraethoxy orthosilicate gas and nitrogen gas which is the dilute gas are fed into the reactor 10, both the gases flow from the inlet part 10b towards the outlet part 10c, via the necked-down part 10a above the silicon semiconductor substrate 12 under a normal pressure environment. As a result, there are formed both a gas flow of tetraethoxy orthosilicate gas and a gas flow of nitrogen gas above the silicon semiconductor substrate 12. It is desirable that both the gas flows are orderly flows without causing turbulence above the silicon semiconductor substrate 12 at this point in time, and that both the gas flows are laminar flows forming respective layers.

Both the gas flows are formed in the necked-down part 10a of the reactor 10, where the silicon semiconductor substrate 12 is disposed, under the normal pressure environment, and the surface of the silicon semiconductor substrate 12 is irradiated with the xenon light rays from the eximer lamp 17 as necessary through the transmissive window 16. The tetraethoxy orthosilicate gas is excited by such irradiation with the xenon light rays, thereby causing growth of the silicon oxide film on top of the silicon semiconductor substrate 12.

Since the transmissive window 16 is warmed up by the temperature control function provided therein, deposition of the silicon oxide film on the transmissive window 16 can be prevented. Thus, clouding of the transmissive window 16 can be prevented, so that the effect of irradiation with the xenon light rays from the light source described above can be adequately maintained.

Examples of specific operation conditions for the CVD system 101 are shown hereinafter as Example 1 and Example 2.

### EXAMPLE 1

size of the housing 11: 50 cm (L)×40 cm (W)×20 cm (H), 10 cm in wall thickness

size of the silicon semiconductor substrate 12: dia. 5 to 12 in illuminance of the xenon light rays: 10 mW/cm²

flow rate of tetraethoxy orthosilicate gas: 0.1 to 1.2 cc/min

flow rate of nitrogen gas: 100 to 300 cc/min

spacing between the susceptor 13 and the transmissive window 16: 10 to 20 mm

temperature at the susceptor 13: 100° C.

temperature at the transmissive window 16: 170° C.

temperature at the heater 14a and the heater 15a: 150° C.

temperature at the upper heater 19a: 130° C.

temperature at the lower heater 19b: 120° C.

### EXAMPLE 2

concentration and temperature of tetraethoxy orthosilicate gas: 0.26%, 40° C.

pressure and temperature of nitrogen gas: 750 Torr, room temperature

time for the formation of an insulation film: 15 min

illuminance of the xenon light rays: 25 mW/cm

temperature inside the reactor 10: 80° C.

temperature at the transmissive window 16: room temperature

Conditions other than those described as above are the same as those of Example 1.

A graph in FIG. 2 shows results of a spectrochemical analysis of a silicon oxide film (formation rate: about 50 Å/min) obtained according to Example 2, conducted by Fourier transform infrared spectrometry (FT-IR). In the graph, the horizontal axis indicates the reciprocal of the wavelength of infrared light rays irradiated to the insulation film, which is the testpiece for the spectrochemical analysis, that is, the wave number (cm⁻¹), and the vertical axis indicates absorbance (optional unit).

According to the results of the spectrochemical analysis, shown in FIG. 2, it is demonstrated by the graph that SiO₂ composing the silicon oxide film is formed on top of the silicon semiconductor substrate 12.

With the CVD system 101 according to the embodiment 1, because the inside of the reactor 10 is placed in a nitrogen atmosphere when executing a CVD method employing the vacuum ultraviolet rays such as the xenon light rays as described in the foregoing, it becomes possible to form an insulation film on top of the silicon semiconductor substrate 12 under a normal pressure environment.

Accordingly, there is no need of keeping the inside of the reactor 10 in a vacuum condition when forming the film as described above, so that the CVD method employing the vacuum ultraviolet rays can be executed economically and with ease.

Further, since the reactor 10, the transmissive window 16, the susceptor 13, and so forth are provided with the temperature control function, respectively, it is possible to prevent reaction products of tetraethoxy orthosilicate gas from sticking to the transmissive window 16, and other regions when forming the film. As a result, reduction in the effect of irradiation with irradiated light rays due to the clouding of the transmissive window 16 as described in the foregoing can be prevented, and an adequate effect of irradiation can be maintained, so that an excellent effect of film formation can be ensured.

Embodiment 2

With a CVD system 102 according to the embodiment 2 of the invention, use is made of the same vacuum ultraviolet rays as used in the CVD system 101 according to the embodiment 1 in order to continuously form the silicon oxide film on top of a plurality of the silicon semiconductor substrates 12.

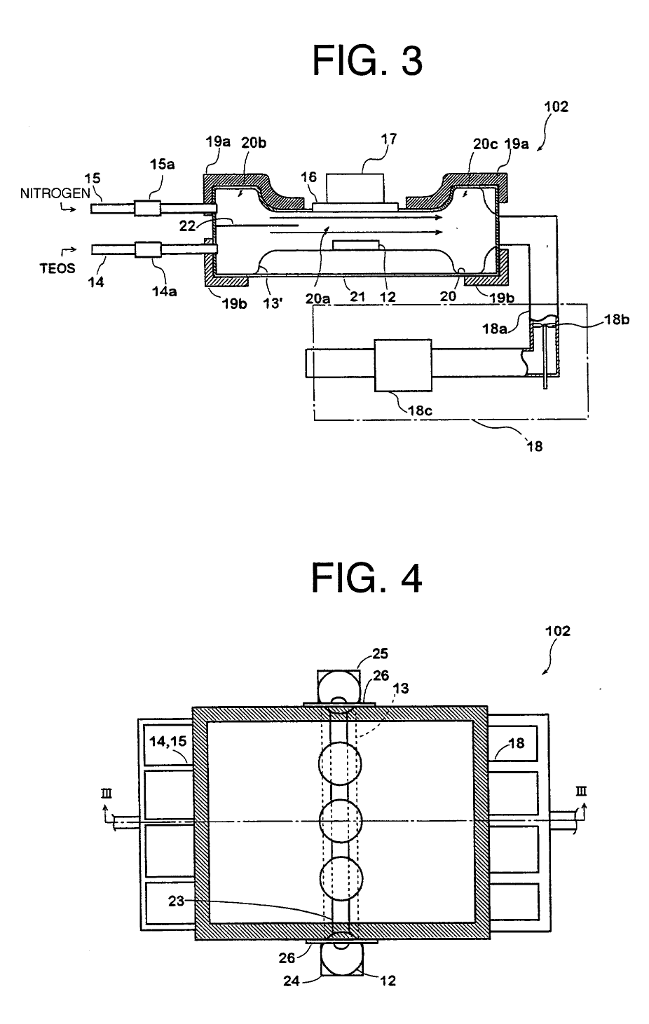

FIGS. 3 and 4 are both views showing the construction of the CVD system 102, and FIG. 3 is a sectional view taken on line III-III in FIG. 4 showing a top view of the CVD system 102. In the CVD system 102, constituent parts having a function corresponding to that of corresponding parts in the CVD system 101 according to the embodiment 1 are denoted by like reference numerals.

As shown in FIG. 3, the CVD system 102 comprises a housing 21 defining a reactor 20 for forming the insulation film on top of the plurality of the silicon semiconductor substrates 12. As with the CVD system 101 according to the embodiment 1, tetraethoxy orthosilicate gas and nitrogen gas are fed And into the reactor 20 via a stock gas feed tube 14 and a dilute gas feed tube 15, respectively.

A necked-down part 20a of the reactor 20 is extended to an inlet part 20b and an outlet part 20c of the reactor 20 via a constricted part thereof, defined by a smoothly curved face, provided at respective edges of the necked-down part 20a. Further, a susceptor 13′ disposed inside the reactor 20 is made up of the sidewalls of the necked-down part 20a. Accordingly, both the gases described above are guided in the form of a smooth orderly flow on the horizontal plane from the inlet part 20b towards the outlet part 20c after passing over the plurality of the silicon semiconductor substrates 12 retained by the susceptor 13′.

The inlet part 20b of the reactor 20 is provided with a parting plate 22 extending inside the reactor 20 from the sidewall of the housing 21, on one side thereof, in order to generate orderly flows of both the gases such that respective laminar flows are formed. The parting plate 22 is installed between both the gas feed tubes on the sidewall of the housing 21, defining the inlet part 20b, so as to protrude from the sidewall towards the necked-down part 20a. The parting plate 22 can be made up of, for example, a stainless steel plate, and is preferably provided with a heater for adjustment of temperature thereof.

As shown in FIG. 4, the CVD system 102 further comprises a transfer belt 23 installed on a horizontal plane crossing a flow path inside the reactor 20 for continuously transferring the silicon semiconductor substrates 12 in a direction normal to the direction of the flow path, a loader 24 for placing the silicon semiconductor substrates 12 on the transfer belt 23 for sending in sequence the silicon semiconductor substrates 12 to the reactor 20, and an unloader 25 for receiving the silicon semiconductor substrates 12 delivered in sequence from the reactor 20 by the transfer belt 23. The transfer belt 23 can be made of a metallic material such as, for example, stainless steel.

Further, as shown in FIG. 4, on both sides of the housing 21 where the loader 24 and the unloader 25 are installed respectively, there is disposed a nitrogen curtain 26 for blowing out nitrogen gas in order to prevent outside air from making ingress into the reactor 20 upon sending-in and sending-out of the silicon semiconductor substrates 12 by the transfer belt 23.

With the CVD system 102, when the plurality of the silicon semiconductor substrates 12 are sequentially sent into the reactor 20 by the transfer belt 23, respective gas flows of tetraethoxy orthosilicate gas and nitrogen gas, oriented in a direction normal to the direction of transfer by the transfer belt 23, are formed over the respective silicon semiconductor substrates 12. Thus, as with the CVD system 101 according to the embodiment 1, growth of an insulation film takes place on the respective silicon semiconductor substrates 12 upon irradiation thereof with xenon light rays for the formation of the film.

An example of temperature conditions for the CVD system 102 is shown hereinafter as Example 3.

### EXAMPLE 3

a transmissive window 16: at 170° C.

a heater 15a: at 160° C.

a heater 14a: at 150° C.

an upper heater 19a: at 150° C.

a lower heater 19b: at 140° C.

a susceptor 13′: at 100° C.

With the CVD system 102 according to the embodiment 2 of the invention, the insulation film can be continuously formed on the plurality of the silicon semiconductor substrates 12 in addition to the advantageous effect of the CVD system 101, so that an operation for the formation of the insulation film can be more efficiently executed.

Furthermore, since the reactor 20 of the CVD system 102 is provided with the constricted part defined by the smoothly curved face, extending to the necked-down part, and the parting plate 22, it is possible to form with reliability orderly laminar flows of tetraethoxy orthosilicate gas on the silicon semiconductor substrates 12, thereby realizing uniform growth of the insulation film on the silicon semiconductor substrates 12.

Embodiment 3

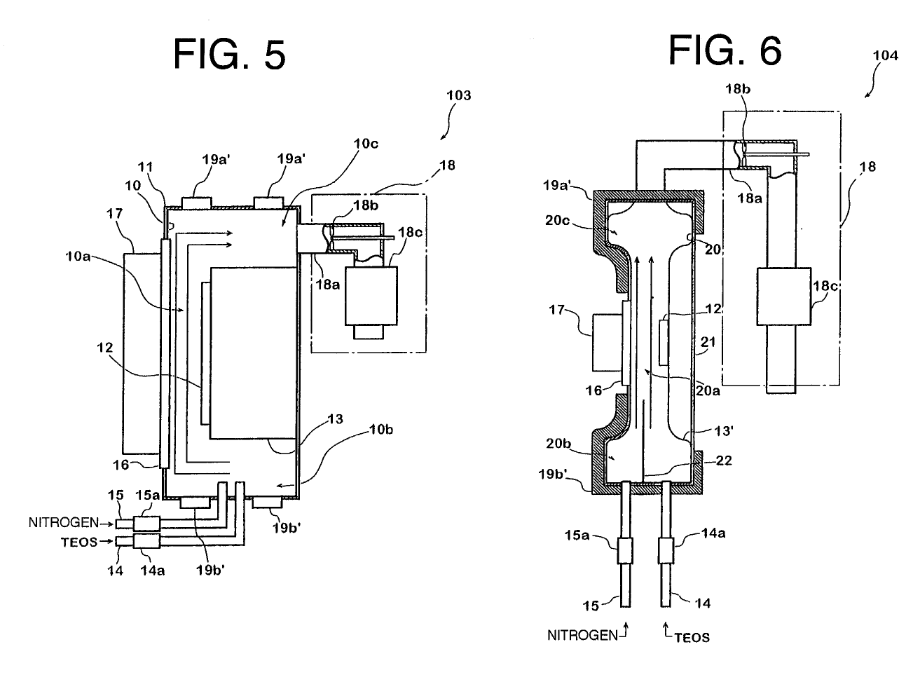

A CVD system 103 according to the embodiment 3 of the invention, shown in FIG. 5, is constructed such that both the gases are caused to flow in the direction vertical to the horizontal plane inside a reactor 10 from the lower part thereof to the upper part thereof. As shown in FIG. 5, the CVD system 103 is in effect the same as the previously described CVD system 101 according to the embodiment 1 except the constitution of a susceptor 13, and can be made up by setting both the gas feed tubes of CVD system 101 upright in the lower part of the CVD system 103.

In the CVD system 103, the previously described silicon semiconductor substrate 12 is to be disposed vertically inside the reactor 10, and consequently, in order to retain the silicon semiconductor substrate 12 in the vertical posture, the susceptor 13 is provided with a holding mechanism such as, for example, a vacuum chuck mechanism.

On the ceiling and the bottom of a housing 11 of the CVD system 103, there are installed an upper heater 19a′ and a lower heater 19b′, respectively, for warming the inside of the reactor 10.

With the CVD system 103, tetraethoxy orthosilicate gas and nitrogen gas are fed into the reactor 10 as with the case of the CVD system 101 according to the embodiment 1, whereupon both the gases flow from an inlet part 10b disposed in the lower part of the reactor 10 towards an outlet part 10c disposed in the upper part thereof after passing over the silicon semiconductor substrate 12 disposed in a necked-down part 10a of the reactor 10.

As a result, there are formed both a gas flow of tetraethoxy orthosilicate gas and a gas flow of nitrogen gas above the silicon semiconductor substrate 12, and when the surface of the silicon semiconductor substrate 12 is irradiated with xenon light rays in order to form an insulation film thereon, growth of the insulation film takes place on the silicon semiconductor substrate 12.

An example of temperature conditions for the CVD system 103 is shown hereinafter as Example 4.

### EXAMPLE 4

a transmissive window 16: at 170° C.

a heater 15a: at 150° C.

a heater 14a: at 150° C.

an upper heater 19a′: at 120° C.

lower heater 19b′: at 130° C.

a susceptor 13: at 100° C.

With the CVD system 103 according to the embodiment 3 of the invention, it is possible to prevent foreign matter such as something like a film growing on the sidewalls of the reactor 10 from falling down on the silicon semiconductor substrate 12 in addition to the advantageous effect of the embodiment 1, because the silicon semiconductor substrate 12 is disposed in the vertical posture inside the reactor 10.

Embodiment 4

A CVD system 104 according to the embodiment 4 of the invention, shown in FIG. 6, is constructed such that both the gases are caused to flow in the direction vertical to the horizontal plane inside a reactor 10 from the lower part thereof to the upper part thereof as with the CVD system 103 according to the embodiment 3 in order to continuously form the previously described insulation film on top of a plurality of the silicon semiconductor substrates 12. The CVD system 104 is in effect the same as the previously described CVD system 102 according to the embodiment 2 except the constitution of a susceptor 13′, and can be made up by setting both the gas feed tubes of CVD system 102 upright in the lower part of the CVD system 104.

In the CVD system 104, the silicon semiconductor substrates 12 are to be disposed vertically inside a reactor 20 as with the case of the embodiment 3, and consequently, in order to retain the silicon semiconductor substrates 12 in the vertical posture, the susceptor 13′ is provided with a holding mechanism such as, for example, a vacuum chuck mechanism.

On the ceiling and the bottom of a housing 21 of the CVD system 104, there are installed an upper heater 19a′ and a lower heater 19b′, respectively, as with the case of the embodiment 3, for warming the inside of the reactor 20 as necessary.

With the CVD system 104, when the plurality of the silicon semiconductor substrates 12 are sequentially sent into the reactor 20 by the transfer belt 23, respective gas flows of tetraethoxy orthosilicate gas and nitrogen gas, oriented in a direction normal to the direction of transfer by the transfer belt 23, that is, in a direction from the lower part of the reactor 20 towards the upper part thereof, are formed over the respective silicon semiconductor substrates 12. Thus, as with the CVD system 102 according to the embodiment 2, growth of an insulation film takes place on the respective silicon semiconductor substrates 12 upon irradiation thereof with xenon light rays for the formation of the insulation film on the plurality of the silicon semiconductor substrates 12

An example of temperature conditions for the CVD system 104 is shown hereinafter as Example 5.

### EXAMPLE 5

a transmissive window 16: at 170° C.

a heater 15a: at 150° C.

a heater 14a: at 150° C.

an upper heater 19a′: at 120° C.

a lower heater 19b′: at 130° C.

a susceptor 13′: at 100° C.

With the CVD system 104 according to the embodiment 4 of the invention, the insulation film can be continuously formed on the plurality of the silicon semiconductor substrates 12 in addition to the advantageous effect of the embodiment 3, so that an operation for the formation of the insulation film can be more efficiently executed.

Embodiment 5

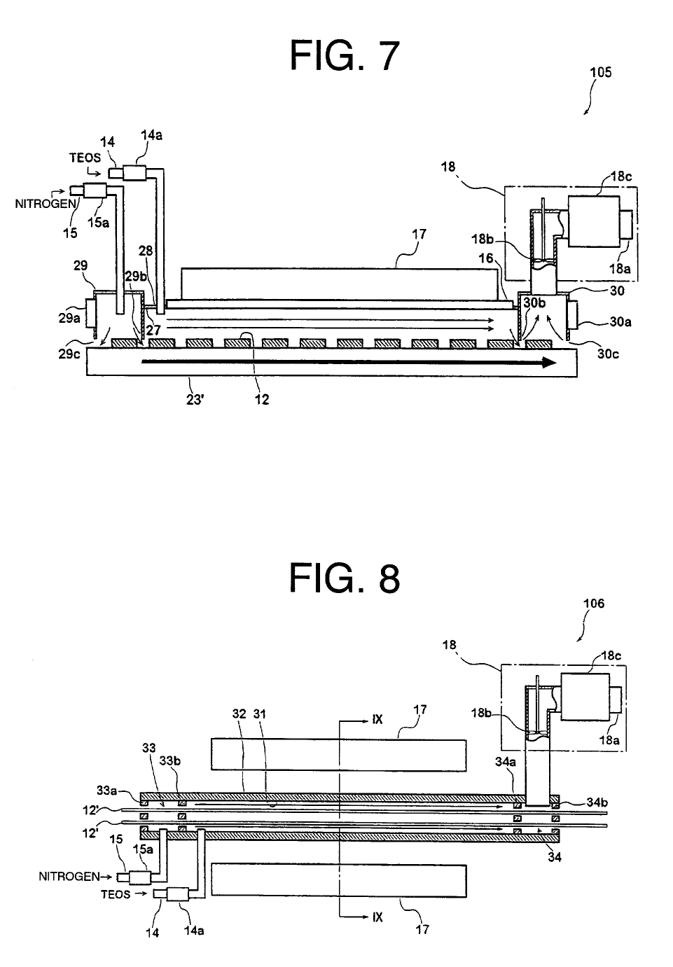

With a CVD system 105 according to the embodiment 5 of the invention, shown in FIG. 7, a plurality of the previously described silicon semiconductor substrates 12 are sequentially transferred in the same direction as that of flows of both the gases by a transfer belt 23′ in order to continuously form an insulation film on the plurality of the silicon semiconductor substrates 12 in a reactor 27 of the CVD system 105. The transfer belt 23′ executes a transfer operation from one end of a housing 28 defining the reactor 27 towards the other end of the housing 28.

As shown in FIG. 7, the CVD system 105 is provided with a pressurizing chamber 29 in the front of the reactor 27, and a depressurizing chamber 30 at the back thereof in order to prevent outside air from being dragged into the reactor 27. On the outer walls of the pressurizing chamber 29 and the depressurizing chamber 30, there are installed a heater 29a and a heater 30a, respectively.

As described in the foregoing, stainless steel may be used as material for the housing 28, and the dimensions thereof may be 200 cm in length, 40 cm in width, and 20 cm in height.

Nitrogen gas is fed from a dilute gas feed tube 15 into the pressurizing chamber 29, and the nitrogen gas fed into the pressurizing chamber 29 is fed into the reactor 27 through a feed inlet 29b which is open to the reactor 27, defining a transfer path of the silicon semiconductor substrates 12, while a part of the nitrogen gas is discharged to outside air through a discharge outlet 29c which is open to outside air, defining the transfer path. Nitrogen gas discharged from the discharge outlet 29c blocks out outside air proceeding from the discharge outlet 29c towards the reactor 27 through the pressurizing chamber 29. As a result, the pressurizing chamber 29 prevents outside air from making ingress into the reactor 27, thereby fulfilling the same function as that of the nitrogen curtain described in the embodiment 2.

Similarly, the depressurizing chamber 30 is linked to the reactor 27 through a first suction inlet 30b defining the transfer path, and is open to the air through a second suction inlet 30c defining the transfer path. Both the gases entering from the first suction inlet 30b and the air entering from the second suction inlet 30c are sucked in by the agency of the same exhaust mechanism 18 as described hereinbefore.

Accordingly, the air entering from the second suction inlet 30c defining the transfer path is prevented from flowing into the reactor 27 through the first suction inlet 30b.

Thus, as with the case of the embodiment 2, outside air is prevented from making ingress into the reactor 27 by an outside air blocking mechanism (29, 30).

From a stock gas feed tube 14, tetraethoxy orthosilicate gas is fed into the reactor 27. The tetraethoxy orthosilicate gas and nitrogen gas flow into the depressurizing chamber 30 after passing over the plurality of the silicon semiconductor substrates 12 disposed in the reactor 27.

With the CVD system 105, since the plurality of the silicon semiconductor substrates 12 are placed directly on the transfer belt 23′, the transfer belt 23′ is preferably provided with a function for controlling temperature of the silicon semiconductor substrates 12.

With the CVD system 105, the tetraethoxy orthosilicate gas and nitrogen gas are fed into the reactor 27 as described in the foregoing, whereupon flows of both the gases, oriented in the same direction as the direction of transfer by the transfer belt 23′, are formed over the respective silicon semiconductor substrates 12, and upon irradiation thereof with xenon light rays for the formation of the insulation film on the respective silicon semiconductor substrates 12, growth of the insulation film takes place on the respective silicon semiconductor substrates 12.

An example of temperature conditions for the CVD system 105 is shown hereinafter as Example 6.

### EXAMPLE 6

a transmissive window 16: at 170° C.

a heater 15a: at 150° C.

a heater 14a: at 150° C.

an upper heater 29a: at 130° C.

a lower heater 30a: at 130° C.

a transfer belt 23′: at 100° C.

With the CVD system 105 according to the embodiment 5 of the invention, the insulation film can be continuously formed on the plurality of the silicon semiconductor substrates 12 in addition to the advantageous effect of the CVD system 101 according to the embodiment 1, so that an operation for the formation of the insulation film can be more efficiently executed.

In the reactor 27 of the CVD system 105, since the transfer direction of the silicon semiconductor substrates 12 coincides with the direction of the flows of both the gases, it is possible to vary film quality, density, refractive index, and so forth, in the direction of the depth of the film formed by changing setting of temperature conditions, gas concentration, and so forth.

More specifically, for example, by providing a temperature gradient as necessary between the temperature at the pressurizing chamber 29 and the temperature at the depressurizing chamber 30, a film density can be easily varied in a process of film growth on the silicon semiconductor substrates 12, thereby varying respective refractive indexes of the plurality of the silicon semiconductor substrates 12.

It is also possible to form a bi-layer film, each layer having a different refractive index, on the respective silicon semiconductor substrates 12 by feeding a trace quantity of oxygen into the reactor 27 from around the central part thereof.

With the CVD system 105 according to the present embodiment, there is shown the case where the transfer direction of the silicon semiconductor substrates 12 coincides with the direction of the flows of both the gases, however, it is possible to set such that the direction of the flows of both the gases is opposed to the transfer direction of the silicon semiconductor substrates 12.

Embodiment 6

With a CVD system 106 according to the embodiment 6 of the invention, shown in FIG. 8, the insulation film described above is formed on band-like members 12′ made up of a glass fiber, metal wire, and so forth.

As shown in FIG. 8, the CVD system 106 is provided with two lengths of cylindrical glass tubes, each serving as a housing 32 defining a reactor 31, and at opposite ends of the respective housings 32, there are installed a pressurizing chamber 33 and a depressurizing chamber 34, fulfilling the same function as that of those in the embodiment 5, corresponding thereto, defined by a pair of partition walls 33a, 33b, and a pair of partition walls 34a, 34b, respectively, and provided with through holes each for allowing a band-like member to pass therethrough, respectively. Further, in the respective reactors 31, there are disposed two lengths of the band-like members 12′, 12′ with a spacing provided in the vertical direction therebetween in such a way as to penetrate through the pressurizing chamber 33 and the depressurizing chamber 34 via the respective through holes of the partition walls 33a, 33b, and the partition walls 34a, 34b.

The respective housings 32 are each preferably equipped with, for example, a spiral heater, thereby adjusting the temperature inside the reactor 31 including the pressurizing chamber 33 and the depressurizing chamber 34.

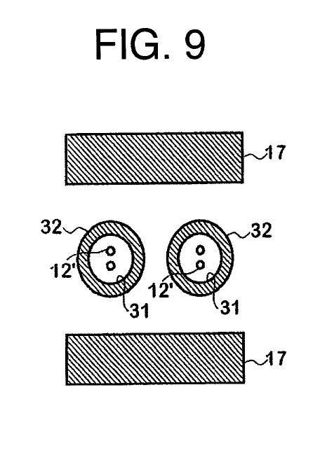

FIG. 9 is a cross-sectional view of the CVD system 106, taken on line IX-IX in FIG. 8. As shown in FIG. 9, with the CVD system 106, there are employed two units of eximer lamps 17, 17, disposed with a spacing in the vertical direction provided therebetween such that respective irradiation faces thereof are opposed to each other, and two units of the housings 32 are disposed side by side horizontally between the two units of eximer lamps 17, 17. The number of the housings 32 may be increased or decreased as necessary.

With the CVD system 106, nitrogen gas is fed from a dilute gas feed tube 15 into the reactor 31 through the pressurizing chamber 33 as with the case of the CVD system 105 according to the embodiment 5, and tetraethoxy orthosilicate gas is fed from a stock gas feed tube 14 into the reactor 31. As a result, there are formed flows of both the gases, moving in the axial direction of the respective band-like members 12′, around the periphery thereof as seen in section, and the respective band-like members 12′ is irradiated with xenon light rays in order to form an insulation film on the respective band-like members 12′. In consequence, growth of the insulation film with substantially uniform thickness in size, formed so as to surround the respective band-like members 12′, takes place on the respective band-like members 12′.

Now, an examples of operation conditions for the CVD system 106 is shown hereinafter as Example 7.

### EXAMPLE 7

size of the housing 32: 200 cm (length)×4 cm (dia.), 5 cm in wall thickness

illuminance of the xenon light rays: 10 mW/cm²

flow rate of tetraethoxy orthosilicate gas: 0.01 to 0.12 cc/min

flow rate of nitrogen gas: 10 to 30 cc/min

spacing between the inner wall of the glass tube (32) and the respective band-like members 12′: 10 to 20 mm temperature at the glass tube (32): 170° C.

In forming the insulation film on band-like members made of glass fiber with the CVD system 106 according to the embodiment 6, it is possible to form the insulation film having substantially uniform thickness in the axial and peripheral directions thereof.

With the previously described embodiments, tetraethoxy orthosilicate gas is used as the starting material for the insulation film, however, besides the above, use may be made of an organic nonmetal gas such as hexamethyldisiloxane [(CH₃)₃SiOSi(CH₃)₃: HMDSO], tetramethylcyclotetrasiloxane [(Si₄C₄H₁₈O₄: TOMCATS)], and fluorotriethoxysilane [Si(OC₂H₅)₃F: FTES]

Further, when forming a metal film, use may be made of an organic metal gas such as tungsten hexacarbonyl [W(CO)₆] as a stock gas.

Still further, with the embodiments described hereinbefore, the silicon semiconductor substrate, the glass fiber, and so forth are used for the base member and the band-like member on which the insulation film is to be formed. Besides these, however, use may be made a member formed of material not evolving oxygen gas and water vapor in quantity as much as blocking the formation of the film, such as a metal sheet, a plastic sheet, a glass sheet, an aluminum wire, a copper wire, an organic fiber, and so forth.

With the method of forming a film according to the invention, and the CVD system for executing the method, according to the invention, the vacuum ultraviolet rays can be effectively irradiated through the organic gas onto the base member under a normal pressure environment by keeping the inside of the reactor in the nitrogen atmosphere or the inert gas atmosphere as described in the foregoing.

Accordingly, it becomes possible to form the film under the normal pressure environment by use of the vacuum ultraviolet rays, so that the film such as the insulation film or the metal film can be economically and easily formed without the use of a vacuum equipment, which is costly.

The present invention may be applicable to a CVD system. For example, a CVD system including a housing defining a reactor in which a base member for causing growth of a film is disposed; a stock gas feed tube for guiding an organic gas used as the starting material for the film into the reactor; a dilute gas feed tube for guiding a dilute gas into the reactor for dilution of the organic gas; a light source of vacuum ultraviolet rays with which the base member is irradiated; and an exhaust mechanism for executing an exhaust operation so as to keep the inside of the reactor under a normal pressure atmosphere, wherein growth of the film takes place on the base member by the agency of the organic gas and the dilute gas.

In the above system, the organic gas and the dilute gas fed into the reactor by way of the stock gas feed tube and dilute gas feed tube, respectively, can be exhausted after passing over the base member, and the base member is subjected to vacuum ultraviolet irradiation for the formation of the film thereon.

Further, the reactor of the system can be provided with an inlet part through which the organic gas and the dilute gas are fed into the reactor, an outlet part through which both the gases fed through the inlet part 10b are discharged, and a necked-down part defined between the inlet part and the outlet part, the base member being disposed in the necked-down part.

The housing of the system can be provided with a parting plate for generating orderly flows of both the organic gas and the dilute gas in the reactor in order to form respective laminar flows of both the gases over the base member.

In the above system flows of both the organic gas and the dilute gas may be oriented in the direction vertical to the horizontal plane, and from the lower part of the reactor towards the upper part of the reactor.

The system may further include a transfer mechanism for sequentially sending a plurality of the base members into the reactor and sequentially taking the plurality of the base members out of the reactor, and an outside air blocking mechanism for preventing outside air from making ingress into the reactor at the time when the base members are sent into, or taken out of the reactor by the transfer mechanism.

A transfer direction of the transfer mechanism coincides with the direction of flows of both the gases in the system.

Finally, in the system, a transfer direction of the transfer mechanism is normal to the direction of flows of both the gases.

What is claimed is:

1. A method of forming a film on a base member disposed in a reactor comprising:
introducing an organic gas into the reactor for use as a material gas for the film, and a dilute gas including an inert gas;
irradiating a surface of the base member with vacuum ultraviolet rays; and
forming the film on the base member under a normal pressure atmosphere.

2. A method of forming a film according to claim 1, wherein the base member is a sheet-like member.

3. A method of forming a film according to claim 2, wherein the sheet-like member is a member selected from the group consisting of a silicon semiconductor substrate, a metal sheet, a plastic sheet, and a glass sheet.

4. A method of forming a film according to claim 1, wherein the base member is a band-like member.

5. A method of forming a film according to claim 4, wherein the band-like member is a member formed of a constituent material selected from the group consisting of a glass fiber, a metal, and an organic fiber, or a composite material made thereof.

6. A method of forming a film according to claim 1, wherein the organic gas is an organic nonmetal gas.

7. A method of forming a film according to claim 6, wherein the organic nonmetal gas is a gas selected from the group consisting of tetraethoxy orthosilicate gas [Si(OC₂H₅)₄], hexamethyldisiloxane [(CH₃)₃SiOSi(CH₃)₃], tetramethylcyclotetrasiloxane (Si₄C₄H₁₈O₄), and fluorotriethoxysilane [Si(OC₂H₅)₃F].

8. A method of forming a film according to claim 1, wherein the organic gas is an organic metal gas.

9. A method of forming a film according to claim 8, wherein the organic metal gas is tungsten hexacarbonyl [W(CO)₆].

10. A method of depositing a material on a substrate comprising:
positioning the substrate in a reaction room;
introducing an inert gas into the reaction room so that the reaction room is filled with the inert gas;
introducing a material gas and the inert gas into the reaction room filled with the inert gas at a normal pressure so that flows of the material gas and the inert gas are formed over the substrate; and
irradiating vacuum ultraviolet lays to the flows of gases so that the material is deposited on the substrate.

11. A method of depositing a material according to claim 10, wherein the material gas is introduced with a flow rate of about 0.1 to 1.2 cc/min. and the inert gas is introduced with a flow rate of about 100 to 300 cc/min.

12. A method of depositing a material according to claim 10, wherein the reaction room is at about 80° C.

13. A method of depositing a material according to claim 10, wherein the material gas is introduced at a temperature of about 40° C.

14. A method of depositing a material according to claim 10, wherein the inert gas is introduced at a room temperature.

15. A method of depositing a material according to claim 10, wherein the vacuum ultraviolet lays are xenon light rays.

16. A method of depositing a material according to claim 10, wherein the flows of gases are orderly follows.

17. A method of depositing a material according to claim 10, wherein the flows of gases are laminar flows.

18. A method of depositing a material according to claim 10, wherein a plurality of substrates are arranged in the reaction room.

19. A method of depositing a material on a substrate comprising:
providing the substrate in a reaction room;
introducing a material gas and an inert gas into the reaction room at a normal pressure so that flows of the material gas and the inert gas are formed over the substrate; and
irradiating vacuum ultraviolet lays to the substrate through flows of gases so that the material is deposited on the substrate.

20. A method of depositing a material according to claim 19, wherein the flows of gases are orderly flows.
